(19) United States
(12) Patent Application Publication
(10) Pub. No.: US 2026/0319136 A1
(43) Pub. Date: Oct. 15, 2026

(54) Anti-Reflective Film And Display Device Including The Same

(71) Applicant: Samsung Display Co., Ltd., Yongin-si (KR)

(72) Inventors: Hyeon Mi Lee, Yongin-si (KR); Man Soo Kim, Yongin-si (KR)

(73) Assignee: Samsung Display Co., Ltd., Yongin-si (KR)

(21) Appl. No.: 19/381,169

(22) Filed: Nov. 6, 2025

(30) Foreign Application Priority Data
Apr. 10, 2025 (KR) 10-2025-0046760

(51) Int. Cl. G02B 1/11; G06F 1/16

(52) U.S. Cl. CPC G02B 1/11; G06F 1/1637

(57) ABSTRACT

An anti-reflective film for a display device is provided. The anti-reflective film includes a substrate; an adhesive layer located on the substrate; a first refractive layer located on the adhesive layer; and a second refractive layer located on the first refractive layer, wherein the refractive index of the first refractive layer may be greater than the refractive index of the second refractive layer, wherein the adhesive layer may include: a first adhesive layer; a second adhesive layer located on the first adhesive layer; a third adhesive layer located on the second adhesive layer; and a fourth adhesive layer located on the third adhesive layer, wherein the refractive index of the second adhesive layer may be greater than the refractive index of the first adhesive layer and smaller than the refractive index of the first refractive layer, and the refractive index of the fourth adhesive layer may be greater than the refractive index third adhesive layer and smaller than the first refractive layer.

### CROSS-REFERENCE TO RELATED APPLICATION

This application claims priority to Korean Patent Application No. 10-2025-0046760 filed on Apr. 10, 2025 in the Korean Intellectual Property Office, and all the benefits accruing therefrom under 35 U.S.C. 119. The contents of the foregoing application are herein incorporated by reference in its entirety.

### TECHNICAL FIELD

The present disclosure relates to an anti-reflective film and a display device including the same.

### BACKGROUND

As an information society develops, the demand for a display device for displaying an image is increasing in various forms. For example, the display device is applied to various electronic devices, such as smartphones, digital cameras, laptop computers, navigation devices, and smart televisions.

When the display device is exposed to external light such as various lights and natural light, an image internally created may not be clearly conveyed to a user due to reflected light, or the user's eyes may become tired. For this reason, the demand for anti-reflection is increasing.

### SUMMARY

Aspects of the present disclosure provide an anti-reflective film having low reflectivity and low color deviation according to the curvature of the anti-reflective film.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there may be provided an anti-reflective film including: a substrate; an adhesive layer located on the substrate; a first refractive layer located on the adhesive layer; and a second refractive layer located on the first refractive layer, wherein a refractive index of the first refractive layer may be greater than a refractive index of the second refractive layer, wherein the adhesive layer may include: a first adhesive layer; a second adhesive layer located on the first adhesive layer; a third adhesive layer located on the second adhesive layer; and a fourth adhesive layer located on the third adhesive layer, wherein a refractive index of the second adhesive layer may be greater than a refractive index of the first adhesive layer and smaller than the refractive index of the first refractive layer, and a refractive index of the fourth adhesive layer may be greater than a refractive index third adhesive layer and smaller than refractive index of the first refractive layer.

The refractive index of the first refractive layer may be equal to or more than 1.9, and the refractive index of the second refractive layer may be equal to or less than 1.6.

The refractive index of the second adhesive layer and the refractive index of the fourth adhesive layer range from 1.6 to 1.9.

A reflectivity of the anti-reflective film may be equal to or less than 1.0%.

A color deviation c* of the anti-reflective film may be equal to or less than 6.0 at a curvature of 0° to 50°, where

c^{x}=\sqrt{da^{*2}+db^{*2}} [Equation 1]

In Equation 1, da* is the change in an a* color coordinate at the curvature relative to an a* color coordinate at 0°, and db* is the change in a b* color coordinate at the curvature relative to a b* color coordinate at 0°.

The anti-reflective film may further include a third refractive layer located on the second refractive layer; and a fourth refractive layer located on the third refractive layer, wherein a refractive index of the third refractive layer may be greater than a refractive index of the fourth refractive layer.

The anti-reflective film may further include a dummy layer between the adhesive layer and the first refractive layer, the first refractive layer, the second refractive layer, the third refractive layer, and the fourth refractive layer, wherein the dummy layer includes a first dummy layer and a second dummy layer located on the first dummy layer, a refractive index of the first dummy layer may be greater than a refractive index of the second dummy layer, and a thickness of the first dummy layer and a thickness of the second dummy layer may be equal to or less than 80 nm.

According to an aspect of the present disclosure, there may be provided a display device including: a display panel; and an anti-reflective film located on the display panel, wherein the anti-reflective film includes: an adhesive layer located on the display panel; a first refractive index layer located on the adhesive layer; and a second refractive index layer located on the first refractive index layer, wherein the refractive index of the first refractive layer may be greater than the refractive index of the second refractive layer, wherein the adhesive layer includes: a first adhesive layer; a second adhesive layer located on the first adhesive layer; a third adhesive layer located on the second adhesive layer; and a fourth adhesive layer located on the third adhesive layer, wherein the refractive index of the second adhesive layer may be greater than the refractive index of the first adhesive layer and smaller than the refractive index of the first refractive layer, and the refractive index of the fourth adhesive layer may be greater than the refractive index third adhesive layer and smaller than the first refractive layer.

The refractive index of the first refractive layer may be equal to or more than 1.9, and the refractive index of the second refractive layer may be equal to or less than 1.6.

The wherein the refractive index of the second adhesive layer and the refractive index of the fourth second adhesive layer range from 1.6 to 1.9.

The reflectivity of the anti-reflective film may be equal to or less than 1.0%.

A reflectivity of the anti-reflective film may be equal to or less than 1.0%.

A color deviation c* of the anti-reflective film may be equal to or less than 6.0 at a curvature of 0° to 50°, where

c^{x}=\sqrt{da^{*2}+db^{*2}}

da* is the change in an a* color coordinate at the curvature relative to an a* color coordinate at 0°, and db* is the change in a b* color coordinate at the curvature relative to a b* color coordinate at 0°.

The anti-reflective film may further include: a third refractive layer located on the second refractive layer; and a fourth refractive layer located on the third refractive layer, wherein the refractive index of the third refractive layer may be greater than the refractive index of the fourth refractive layer.

The anti-reflective film may further include: a dummy layer between the adhesive layer and the first refractive layer, between the first refractive layer, the second refractive layer, the third refractive layer, and the fourth refractive layer, wherein the dummy layer further includes a first dummy layer and a second dummy layer located on the first dummy layer, the refractive index of the first dummy layer is greater than the refractive index of the second dummy layer, and the thickness of the first dummy layer and the thickness of the second dummy layer are equal to or less than 80 nm.

According to an aspect of the present disclosure, there may be provided an electronic device including: a display device providing an image; and a processor transmitting an image data signal to the display device, wherein the display device includes: a display panel; and an anti-reflective film located on the display panel, wherein the anti-reflective film includes: an adhesive layer located on the display panel; a first refractive index layer located on the adhesive layer; and a second refractive index layer located on the first refractive index layer, wherein a refractive index of the first refractive layer is greater than a refractive index of the second refractive layer, wherein the adhesive layer includes: a first adhesive layer; a second adhesive layer located on the first adhesive layer; a third adhesive layer located on the second adhesive layer; and a fourth adhesive layer located on the third adhesive layer, wherein a refractive index of the second adhesive layer may be greater than a refractive index of the first adhesive layer and smaller than the refractive index of the first refractive layer, and a refractive index of the fourth adhesive layer may be greater than a refractive index third adhesive layer and smaller than the first refractive layer.

The refractive index of the first refractive layer may be equal to or greater than 1.9, the refractive index of the second refractive layer may be equal to or less than 1.6, and the refractive index of the second adhesive layer and the refractive index of the fourth adhesive layer range from 1.6 to 1.9.

The reflectivity of the anti-reflective film may be equal to or less than 1.0%.

A color deviation c* of the anti-reflective film may be equal to or less than 6.0 at a curvature of 0° to 50°, where

c^{x}=\sqrt{da^{*2}+db^{*2}}

In Equation 1, da* is the change in an a* color coordinate at the curvature relative to an a* color coordinate at 0°, and db* is the change in a b* color coordinate at the curvature relative to a b* color coordinate at 0°.

The anti-reflective film may further include: a third refractive layer located on the second refractive layer; and a fourth refractive layer located on the third refractive layer, wherein the refractive index of the third refractive layer may be greater than the refractive index of the fourth refractive layer.

The anti-reflective film may further include: a dummy layer between the adhesive layer and the first refractive layer, between the first refractive layer, the second refractive layer, the third refractive layer, and the fourth refractive layer, wherein the dummy layer further includes a first dummy layer and a second dummy layer located on the first dummy layer, the refractive index of the first dummy layer is greater than the refractive index of the second dummy layer, and the thickness of the first dummy layer and the thickness of the second dummy layer are equal to or less than 80 nm.

The anti-reflective film according to an aspect of the present disclosure is an adhesive layer that bonds the substrate and the refractive index layer, and may reduce reflectivity while reducing color deviation due to curvature of the film by using a low refractive index layer/middle refractive index layer/low refractive index layer/middle refractive index layer.

In addition, the anti-reflective film may further include a dummy layer between functional layers in which the low refractive index layers and the high refractive index layers are arranged alternately, thereby improving durability.

The effects of the present disclosure are not limited to the aforementioned effects, and various other effects will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail exemplary aspects thereof with reference to the attached drawings, in which:

FIG. 1 is a perspective view of a display device according to an aspect;

FIG. 2 is an exploded, perspective view of a display device according to an aspect;

FIG. 3 is a side view of a display device according to an aspect;

FIG. 4 is a cross-sectional view of a display panel according to an aspect;

FIG. 5 is a cross-sectional view showing an anti-reflective film in a display device according to a first aspect of the present disclosure;

FIG. 6 is a cross-sectional view illustrating an adhesive layer in an anti-reflective film according to an aspect of the present disclosure;

FIG. 7 is a diagram showing an anti-reflective film in a display device according to a second aspect of the present disclosure;

FIG. 8 is a diagram showing an anti-reflective film in a display device according to a third aspect of the present disclosure;

FIG. 9 is a cross-sectional view illustrating a dummy layer in an anti-reflective film in a display device according to an aspect of the present disclosure;

FIG. 10 is a graph showing reflectivity with respect to wavelength of films in Example 1, Example 2, Comparative example 1, and Comparative example 2;

FIG. 11 is a graph showing color difference (c*) due to the curvature of a film of Example 1;

FIG. 12 is a block diagram of an electronic device according to an aspect; and

FIG. 13 is a view showing electronic devices according to a variety of aspects of the present disclosure.

### DETAILED DESCRIPTION

The advantages and features of the present disclosure, and the methods for achieving them, will become clear with reference to the aspects described below in detail with the accompanying drawings. However, the present disclosure is not limited to the aspects disclosed below, but may be implemented in various different forms, and these aspects are provided only to make the present disclosure complete and to fully inform those skilled in the art.

When elements or layers are referred to as “on” another element or layer, this includes all cases where another layer or another element is interposed directly over or in the middle of the other element. The same reference numerals refer to the same components throughout the specification. The shapes, sizes, ratios, angles, numbers, etc. disclosed in the drawings for explaining the aspects are exemplary, and therefore the present disclosure is not limited to the matters illustrated.

Although the terms “first” and “second” are used to describe various components, these components are not limited by these terms. These terms are only used to distinguish one component from another. Therefore, the first component mentioned below may be the second component within the technical idea of the present disclosure.

Each of the features of the various aspects of the present disclosure may be partially or wholly combined or combined with each other, and various technical connections and operations are possible, and each aspect may be implemented independently of each other or may be implemented together in a related relationship.

Specific aspects will be described below with reference to the attached drawings.

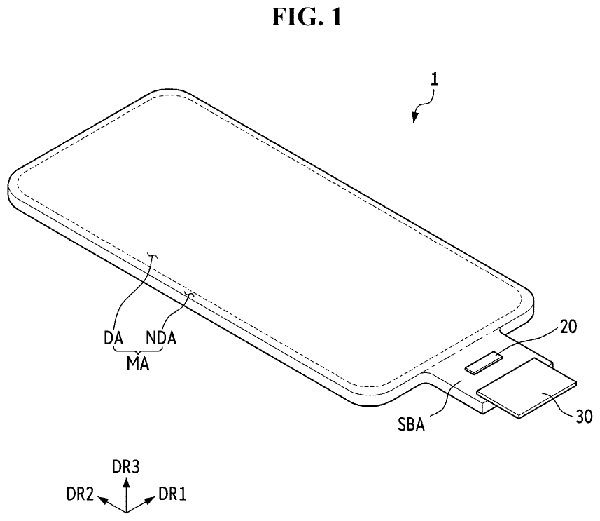

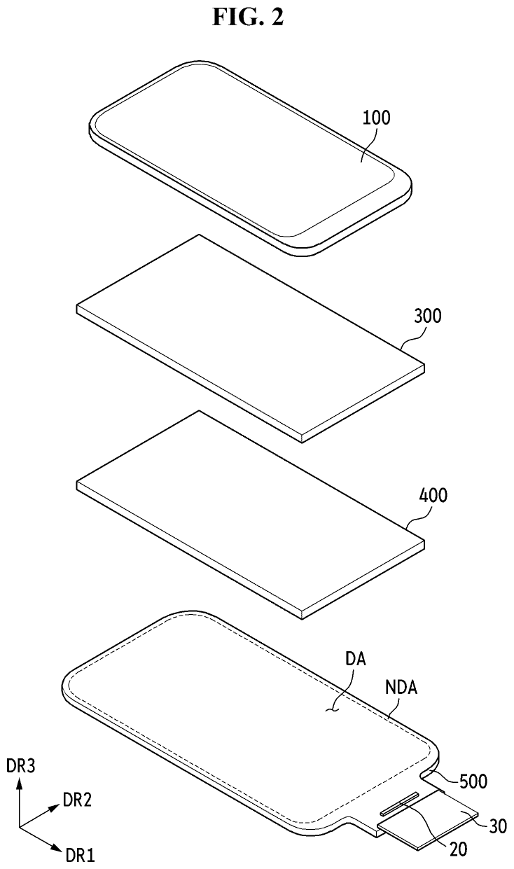

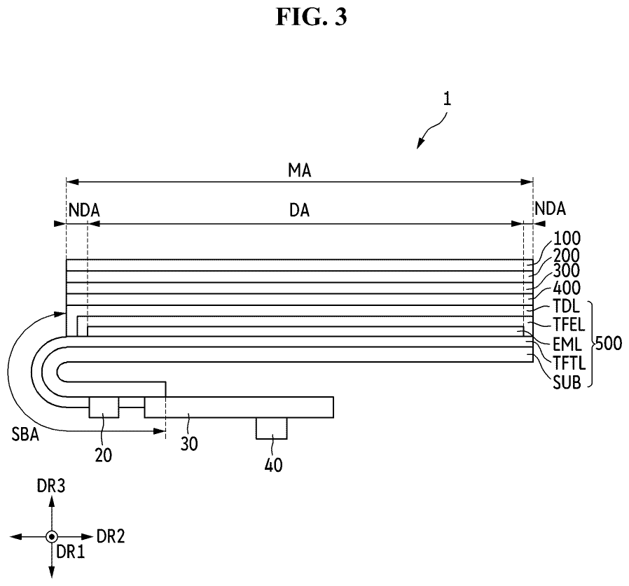

FIG. 1 is a perspective view of a display device according to an aspect. FIG. 2 is an exploded, perspective view of a display device according to an aspect. FIG. 3 is a side view of a display device according to an aspect.

Referring to FIGS. 1 to 3, a display device 1 according to the aspect may include a window member 100, an adhesive member 200, an anti-fingerprint film 300, an anti-reflective film 400 and a display panel 500.

The display device 1 according to the aspect of the present disclosure is for displaying moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things.

According to an aspect of the present disclosure, the display device 1 may be a light-emitting display device such as an organic light-emitting display device using organic light-emitting diodes, a quantum-dot light-emitting display device including quantum-dot light-emitting layer, an inorganic light-emitting display device including an inorganic semiconductor, and a micro-LED display device using micro or nano light-emitting diodes (micro LEDs or nano LEDs). In the following description, an organic light-emitting display device is described as an example of the display device 1 according to the aspect. It is, however, to be understood that aspects of the present disclosure are not limited thereto.

The display device 1 includes a display panel 500, a display driver circuit 20 and a circuit board 30.

The display panel 500 may be formed in a rectangular plane having shorter sides in a first direction DR1 and longer sides in a second direction DR2 intersecting the first direction DR1. In addition, the display panel 500 may have a thickness in a third direction DR3 that intersects the first direction DR1 and the second direction DR2. Each of the corners where the shorter side in the first direction DRI meets the longer side in the second direction DR2 may be rounded with a predetermined curvature or may be a right angle. The shape of the display panel 500 when viewed from the top is not limited to a quadrangular shape, but may be formed in a different polygonal shape, a circular shape, or an elliptical shape. The display panel 500 may be formed flat, but the present disclosure is not limited thereto. For example, the display panel 500 may be formed at left and right ends, and may include a curved portion having a constant curvature or a varying curvature. In addition, the display panel 500 may be flexible so that it can be curved, bent, folded or rolled.

The display panel 500 may include the main area MA and a subsidiary area SBA.

The main area MA may include a display area DA where images are displayed, and a non-display area NDA around the display area DA. The display area DA may occupy most of the main area MA. The display area DA may be arranged at the center of the main area

MA. The non-display area NDA may be arranged adjacent to the display area DA. The non-display area NDA may be located on the outer side of the display area DA. The non-display area NDA may surround the display area DA. The non-display area NDA may be defined as the border of the display panel 500.

The subsidiary area SBA may be extended from one side of the main area MA in the first direction DR1. The length of the subsidiary area SBA in the first direction DRI may be smaller than the length of the main area MA in the first direction DR1. The length of the subsidiary area SBA in the second direction DR2 may be less than the length of the main area MA in the second direction DR2 or may be substantially equal to it. The subsidiary area SBA may be bent and may be arranged under the display panel 500. In this instance, the subsidiary area SBA may overlap with the main area MA in the third direction DR3.

The display driver circuit 20 may generate signals and voltages for driving the display panel 500. The display driver circuit 20 may be implemented as an integrated circuit (IC) and may be attached to the subsidiary area SBA of the display panel 500 by a chip on glass (COG) technique, a chip on plastic (COP) technique, or an ultrasonic bonding. Alternatively, the display driver circuit 20 may be attached on the circuit board 30 by the chip-on-film (COF) technique.

The circuit board 30 may be attached to one end of the subsidiary area SBA of the display panel 500. Accordingly, the circuit board 30 may be electrically connected to the display panel 500 and the display driver circuit 20. The display panel 500 and the display driver circuit 20 may receive digital video data, timing signals, and driving voltages through the circuit board 30. The circuit board 30 may be a flexible printed circuit board, a printed circuit board, or a flexible film such as a chip on film.

A touch driver circuit 40 may be arranged on the circuit board 30. The touch driver circuit 40 may be implemented as an integrated circuit (IC) and may be attached on the circuit board 30.

The touch driver circuit 40 may be electrically connected to a plurality of driving electrodes and a plurality of sensing electrodes of a touch sensing layer TDL. The touch driver circuit 40 may apply a touch driving signal to a plurality of driving electrodes, and may sense a touch sensing signal, for example, a change amount of charge in mutual capacitance, of each of a plurality of touch nodes a plurality of sensing electrodes. The touch driver circuit 40 may determine whether there is a user's touch or near proximity, based on the touch sensing signal of each of the plurality of touch nodes. A user's touch refers to that an object such as the user's finger or a pen is brought into contact with the front surface of the display device 1 located on the touch sensing layer TDL. A user's near proximity refers to that an object such as the user's finger and a pen is hovering over the front surface of the display device 1.

The window member 100 may be attached to the front surface of the anti-fingerprint film 300 by the adhesive member 200. The window member 100 is made of a transparent material, and may be, for example, glass or plastic. For example, the window member 100 may be an ultra thin glass (UTG) having a thickness of 0.1 mm or less or a transparent polyimide film.

The adhesive member 200 may be a transparent adhesive film or a transparent adhesive resin. For example, the adhesive member 200 may include a transparent adhesive such as a pressure sensitive adhesive (PSA) and an optically clear adhesive (OCA). A first adhesive member 300 may include an acrylic adhesive material.

The anti-fingerprint film 300 may be located on the front surface of the window member 100. The anti-fingerprint film 300 can prevent a user's fingerprint from being left on the display device 1.

The anti-reflective film 400 may be located on the front surface of the display panel 500. The anti-reflective film 400 may include a plurality of refractive layers having different refractive indices. The anti-reflective film 400 can reduce reflected light through the plurality of refractive layers. The anti-reflective film 400 is a key feature of the present disclosure, and will be described in detail later.

A light-blocking layer (not shown) for absorbing light incident from the outside, a buffer layer (not shown) for absorbing impact from the outside, and a heat-dissipation layer (not shown) for efficiently discharging heat from the display panel 500 may be further included under the display panel 500.

The light-blocking layer can block transmission of light, thereby preventing elements disposed under the light-blocking layer from being seen from above the display panel 500. The light-blocking layer may include a light-absorbing material such as a black pigment and a black dye.

The buffer layer can absorb external shock to prevent the display panel 500 from being damaged. The buffer layer may be made up of a single layer or multiple layers. For example, the buffer layer may include a polymer resin such as polyurethane, polycarbonate, polypropylene and polyethylene, or may include a material having elasticity such as a rubber and a sponge obtained by foaming a urethane-based material or an acrylic-based material.

The heat-dissipation layer may include a first heat-dissipation layer including graphite or carbon nanotubes, and a second heat-dissipation layer formed as a thin metal film such as copper, nickel, ferrite and silver, which can block electromagnetic waves and have high thermal conductivity.

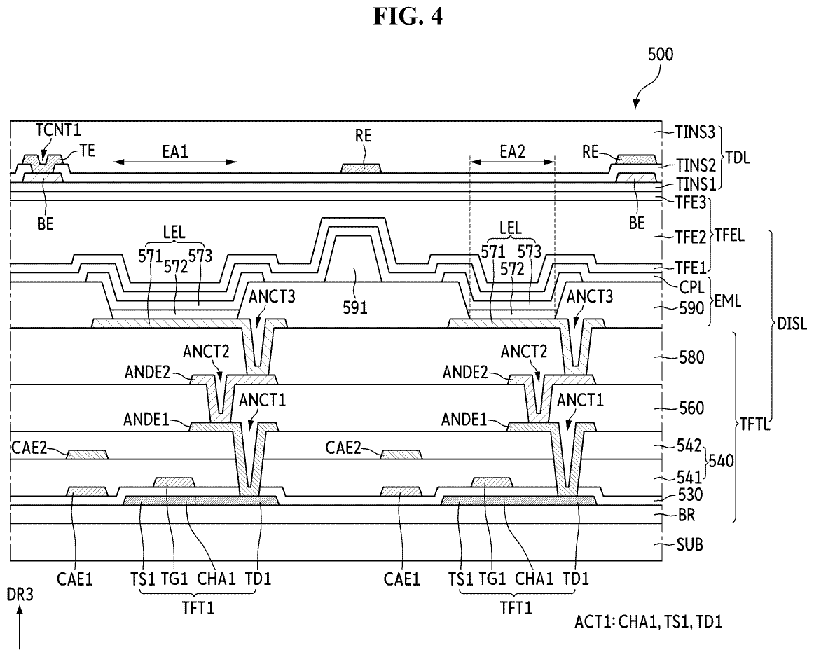

FIG. 4 is a cross-sectional view of a display panel according to an aspect.

Referring to FIG. 4, the display panel 500 may include a substrate SUB, a display layer DISL disposed on the substrate SUB, and a touch sensing layer TDL disposed on the display layer DISL. The display layer DISL may include a thin-film transistor layer TFTL, a light-emitting element layer EML, and an encapsulation layer TFEL.

The thin-film transistor layer TFTL may be arranged on the substrate SUB. The thin-film transistor layer TFTL may include a barrier film BR, a thin-film transistor TFT1, a first capacitor electrode CAE1, a second capacitor electrode CAE2, a first anode connection electrode ANDE1, a second anode connection electrode ANDE2, a gate insulator 530, a first interlayer dielectric film 541, a second interlayer dielectric film 542, a first planarization film 560, a second planarization film 580.

The substrate SUB may be made of an insulating material such as a polymer resin. For example, the substrate SUB may be made of polyimide. The substrate SUB may be a flexible substrate that can be bent, folded, or rolled.

The barrier film BR may be arranged on the substrate SUB. The barrier film BR is a film for protecting the thin-film transistors of the thin-film transistor layer TFTL and an emissive layer 572 of the light-emitting element layer EML. The barrier film BR may be made up of multiple inorganic films stacked on one another alternately. For example, the barrier film BR may be made up of multiple layers in which one or more inorganic layers of a silicon nitride layer, a silicon oxynitride layer, a silicon oxide layer, a titanium oxide layer and an aluminum oxide layer are alternately stacked on one another.

The thin-film transistor layer TFTL may be arranged on the substrate SUB. The thin-film transistor layer TFTL may be arranged in the main area MA and the subsidiary area SBA. The thin-film transistor layer TFTL includes thin-film transistors.

The thin-film transistors TFT1 may be arranged on the barrier film BR. An active layer ACT1 of the thin-film transistor TFT1 may be arranged on the barrier film BR. The active layer ACT1 of the thin-film transistor TFT1 may include polycrystalline silicon, monocrystalline silicon, low-temperature polycrystalline silicon, amorphous silicon, or an oxide semiconductor.

The active layer ACT1 may include a channel region CHA1, a source region TS1 and a drain region TD1. The channel region CHA1 may overlap with a gate electrode TG1 in the third direction DR3 that is the thickness direction of the substrate SUB. The source region TS1 may be arranged on one side of the channel region CHA1, and the drain region TD1 may be arranged on the opposite side of the channel region CHA1. The source region TS1 and the drain region TD1 may not overlap with the gate electrode TG1 in the third direction DR3. The source region TS1 and the drain region TD1 may be formed by doping a silicon semiconductor or an oxide semiconductor with ions or impurities to have conductivity.

The gate insulator 530 may be arranged on the active layer ACT1 of the thin-film transistor TFT1. The gate insulator 530 may include an inorganic layer, for example, a silicon nitride layer, a silicon oxynitride layer, a silicon oxide layer, a titanium oxide layer, or an aluminum oxide layer.

The gate electrode TG1 of the thin-film transistor TFT1 and the first capacitor electrode CAE1 may be arranged on the gate insulator 530. The gate electrode TG1 may overlap with the channel region CHA1 in the third direction DR3. Although the gate electrode TG1 and the first capacitor electrode CAEl are spaced apart from each other in the example shown in FIG. 4, the gate electrode TG1 and the first capacitor electrode CAE1 may be connected with each other as a single piece. The gate electrode TG1 and the first capacitor electrode CAE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric film 541 may be arranged on the gate electrode TG1 of the thin-film transistor TFT1 and the first capacitor electrode CAE1. The first interlayer dielectric film 541 may include an inorganic layer, for example, a silicon nitride layer, a silicon oxynitride layer, a silicon oxide layer, a titanium oxide layer, or an aluminum oxide layer. The first interlayer dielectric film 541 may be made of a plurality of inorganic films.

The second capacitor electrode CAE2 may be arranged on the first interlayer dielectric film 541. The second capacitor electrode CAE2 may overlap the first capacitor electrode CAE1 of the thin-film transistor TFT1 in the third direction DR3. In addition, when the gate electrode TG1 and the first capacitor electrode CAEl are formed as a single piece, the second capacitor electrode CAE2 may overlap the gate electrode TGI in the third direction DR3. Since the first interlayer dielectric film 541 has a dielectric constant, a capacitor can be formed by the first capacitor electrode CAE1, the second capacitor electrode CAE2 and the first interlayer dielectric film 541 arranged therebetween. The second capacitor electrode CAE2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second interlayer dielectric film 542 may be arranged over the second capacitor electrode CAE2. The second interlayer dielectric film 542 may include an inorganic layer, for example, a silicon nitride layer, a silicon oxynitride layer, a silicon oxide layer, a titanium oxide layer, or an aluminum oxide layer. The second interlayer dielectric film 542 may be made of a plurality of inorganic films.

A first anode connection electrode ANDE1 may be arranged on the second interlayer dielectric film 542. The first anode connection electrode ANDEI may be connected to the drain region TD1 of the thin-film transistor TFT1 through a first connection contact hole ANCT1 that penetrates the gate insulator 530, the first interlayer dielectric film 541 and the second interlayer dielectric film 542. The first anode connection electrode ANDE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first planarization film 560 may be disposed over the first anode connection electrode ANDE1 for providing a flat surface over level differences due to the thin-film transistor TFT1. The first planarization film 560 may include an organic film such as an acryl resin, an epoxy resin, a phenolic resin, a polyamide resin and a polyimide resin.

The second anode connection electrode ANDE2 may be located on the first planarization film 560. The second anode connection electrode ANDE2 may be connected to the first anode connection electrode ANDE1 through a second connection contact hole ANCT2 penetrating the first planarization film 560. The second anode connection electrode ANDE2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second planarization film 580 may be arranged on the second anode connection electrode ANDE2. The second planarization film 580 may be formed as an organic film such as an acryl resin, an epoxy resin, a phenolic resin, a polyamide resin and a polyimide resin.

The light-emitting element layer EML may be arranged on the thin-film transistor layer TFTL. The light-emitting element layer EML may be arranged in the display area DA of the main area MA. The light-emitting element layer EML includes light-emitting elements arranged in emission areas.

The light-emitting element layer EML including light-emitting elements LEL and a bank 590 may be arranged on the second planarization film 580. Each of the light-emitting elements LEL includes a pixel electrode 571, an emissive layer 572, and a common electrode 573.

The pixel electrode 571 may be arranged on the second planarization film 580. The pixel electrode 571 may be connected to the second anode connection electrode ANDE2 through a third connection contact hole ANCT3 penetrating the second planarization film 580.

In the top-emission structure in which light exits from the emissive layer 572 toward the common electrode 573, the pixel electrode 571 may be made of a metal material having a high reflectivity such as a stack structure of aluminum and titanium (Ti/Al/Ti), a stack structure of aluminum (Al) and ITO (Indium Tin Oxide) (ITO/Al/ITO), an APC alloy and a stack structure of an APC alloy and ITO (ITO/APC/ITO). The APC alloy is an alloy of silver (Ag), palladium (Pd) and copper (Cu).

The bank 590 may partition the pixel electrode 571 on the second planarization film 580 to define the emission areas EAl and EA2. The bank 590 may be arranged to cover the edges of the pixel electrode 571. The bank 590 may include an organic film such as an acryl resin, an epoxy resin, a phenolic resin, a polyamide resin and a polyimide resin.

In each of the first emission area EAl and the second emission area EA2, the pixel electrode 571, the emissive layer 572 and the common electrode 573 are stacked on one another sequentially, so that holes from the pixel electrode 571 and electrons from the common electrode 573 are recombined with each other in the emissive layer 572 to emit light.

The emissive layer 572 may be arranged on the pixel electrode 571 and the bank 590. The emissive layer 572 may include an organic material to emit light of a certain color. For example, the emissive layer 572 may include a hole transporting layer, an organic material layer, and an electron transporting layer.

The common electrode 573 may be arranged on the emissive layer 572. The common electrode 573 may be arranged to cover the emissive layer 572. The common electrode 573 may be a common layer formed commonly across the first emission area EAl and the second emission area EA2.

In the top-emission organic light-emitting diode, the common electrode 573 may include a transparent conductive material (TCP) such as ITO and IZO that can transmit light, or a semi-transmissive conductive material such as magnesium (Mg), silver (Ag) and an alloy of magnesium (Mg) and silver (Ag). When the common electrode 573 is made of a semi-transmissive metal material, the light extraction efficiency can be increased by using microcavities.

A spacer 591 may be arranged on the bank 590. The spacer 591 may support a mask during a process of fabricating the emissive layer 572. The spacer 591 may be implemented as an organic film such as an acryl resin, an epoxy resin, a phenolic resin, a polyamide resin and a polyimide resin.

According to some aspects of the present disclosure, the display panel 500 may further include a capping layer CPL arranged on the common electrode 573. The capping layer CPL may be made of an inorganic material. For example, the capping layer CPL may include at least one of: silicon nitride, aluminum nitride, zirconium nitride, titanium nitride, hafnium nitride, tantalum nitride, silicon oxide, aluminum oxide, titanium oxide, tin oxide, cerium oxide and silicon oxynitride.

The encapsulation layer TFEL may be arranged on the light-emitting element layer EML. The encapsulation layer TFEL may be arranged in the display area DA and the non-display area NDA of the main area MA. The encapsulation layer TFEL includes at least one inorganic film and at least one organic film for encapsulating the light-emitting element layer.

An encapsulation layer TFEL may be arranged on the common electrode 573. The encapsulation layer TFEL may include at least one inorganic film to prevent permeation of oxygen or moisture into the light-emitting element layer EML. In addition, the encapsulation layer TFEL may include at least one organic film to protect the light-emitting element layer EML from particles such as dust. For example, the encapsulation layer TFEL may include a first inorganic encapsulation film TFE1, an organic encapsulation film TFE2 and a second inorganic encapsulation film TFE3.

The first inorganic encapsulation film TFE1 may be arranged on the common electrode 573, the organic encapsulation film TFE2 may be arranged on the first inorganic encapsulation film TFE1, and the second inorganic encapsulation film TFE3 may be arranged on the organic encapsulation film TFE2. The first inorganic encapsulation film TFE1 and the second inorganic encapsulation film TFE3 may be made up of multiple layers in which one or more inorganic films of a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, etc.

A touch sensing layer TDL may be arranged on the encapsulation layer TFEL. The touch sensing layer TDL includes a first touch insulating film TINS1, connection electrodes BE, a second touch insulating film TINS2, the driving electrodes TE, the sensing electrodes RE, and a third touch insulating film TINS3. The touch sensing layer TDL may sense a touch of a person or an object using touch electrodes.

The first touch insulating film TINS1 may be arranged on the encapsulation layer TFEL. The first touch insulating film TINS1 may be implemented as an inorganic film, for example, a silicon nitride layer, a silicon oxynitride layer, a silicon oxide layer, a titanium oxide layer, or an aluminum oxide layer.

The connection electrode BE may be arranged on the first touch insulating film TINS1. The connection electrode BE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second touch insulating film TINS2 may be arranged over the connection electrodes BE. The second touch insulating film TINS2 may be implemented as an inorganic layer, for example, a silicon nitride layer, a silicon oxynitride layer, a silicon oxide layer, a titanium oxide layer, or an aluminum oxide layer. Alternatively, the second touch insulating film TINS2 may be made of an organic layer such as an acryl resin, an epoxy resin, a phenolic resin, a polyamide resin and a polyimide resin.

The driving electrodes TE and the sensing electrodes RE may be arranged on the second touch insulating film TINS2. The driving electrodes TE and the sensing electrodes RE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The driving electrodes TE and the sensing electrodes RE may overlap with the connection electrodes BE in the third direction DR3. The driving electrodes TE may be connected to the connection electrodes BE through touch contact holes TCNT1 penetrating through the first touch insulating film TINS1.

The third touch insulating film TINS3 may be formed on the driving electrodes TE and the sensing electrodes RE. The third touch insulating film TINS3 may provide a flat surface over the driving electrodes TE, the sensing electrodes RE and the connection electrodes BE which having different heights. The third touch insulating film TINS3 may be made of an organic layer such as an acryl resin, an epoxy resin, a phenolic resin, a polyamide resin and a polyimide resin.

Hereinafter, various aspects of an anti-reflective film 400, which is a main feature of a display device 1 according to an aspect of the present disclosure will be described with reference to the accompanying drawings.

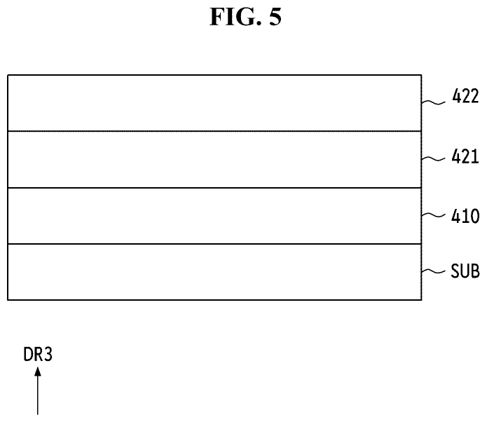

FIG. 5 is a diagram showing an anti-reflective film in a display device according to a first aspect of the present disclosure.

Referring to FIG. 5, an anti-reflective film according to the first aspect may include a substrate SUB, an adhesive layer 410, a first refractive layer 421, and a second refractive layer 422.

The refractive index of the first refractive layer 421 may be greater than the refractive index of the second refractive layer 422. The first refractive layer 421 may work as a high refractive index layer. The second refractive layer 422 may work as a low refractive index layer.

The refractive index of the second refractive layer 422 may range from 1.20 to 1.60, but the present disclosure is not limited thereto. The second refractive index layer 422 may include, but is not limited to, at least one of silicon resin, silica, silicon oxide (SiOx), and silicon dioxide (SiO₂). The second refractive index layer 422 is not limited to the above-listed materials and may include any material as long as it can exhibit a low refractive index.

The refractive index of the first refractive layer 421 may be equal to or greater than 1.9, but the present disclosure is not limited thereto.

The first refractive layer 421 may include at least one of: silicon nitride (Si₃N₄), aluminum nitride (AlN), zirconium nitride (ZrN), chromium nitride (CrN), titanium nitride (TiN), manganese nitride (Mn₄N), iron nitride (FeNx), cobalt nitride (CoNx), nickel nitride (Ni₃N), copper nitride (Cu₃N), zinc nitride (Zn₂N₃), vanadium nitride (VN), molybdenum nitride (MO₂N), hafnium nitride (HfN), germanium nitride (Ge₃N₄), lead nitride (Pb(N₃)₂), titanium niobate (Ti₄Nb₃O₃₅), titanium dioxide (TiO₂), zirconium dioxide (ZrO₂), lithium niobate (LiNbO₃), lithium tantalate (LiTaO₃), and Lanthanum Titanium (LaTiO₂). The high refractive index layer 421 is not limited to the above-listed materials and may include any material as long as it can exhibit a high refractive index.

The thickness t1 of the first refractive layer 421 and the thickness t2 of the second refractive layer 422 may be equal to each other or different from each other. The thickness t1 of the first refractive layer 421 and the thickness t2 of the second refractive layer 422 may be determined by considering the characteristics of the anti-reflective film 400, such as the target reflection wavelength, rigidity, durability, and reflectance.

The thickness t1 of the first refractive layer 421 and the thickness t2 of the second refractive layer 422 may be calculated by Equation 1 below:

$$t = \frac{λ}{4 n} \qquad [ Equation 1 ]$$

where t denotes the thickness t1 or t2 of the first refractive layer 421 or the second refractive layer 422 in the anti-reflective film 400, 2 denotes the target reflection wavelength of the anti-reflective film 400, and n denotes the refractive index of the first refractive layer 421 or the second refractive layer 422.

For example, when the target reflection wavelength of the anti-reflective film 400 is 500 nm, and the refractive index of the first refractive layer 421 is 2.3, the thickness of the first refractive layer 421 may be approximately 54 nm. In addition, when the target reflection wavelength of the anti-reflective film 400 is 500 nm and the refractive index of the second refractive layer 422 is 1.2, the thickness of the second refractive layer 422 may be approximately 104 nm.

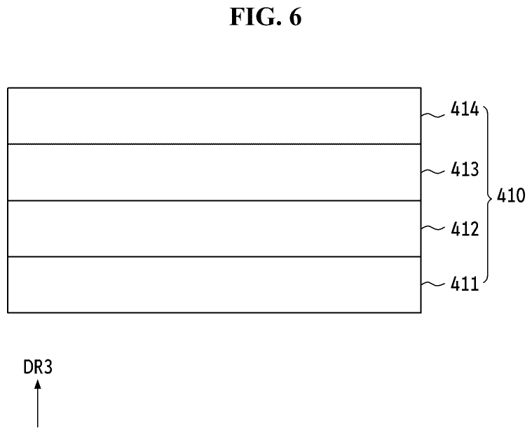

FIG. 6 is a cross-sectional view illustrating an adhesive layer in an anti-reflective film according to an aspect of the present disclosure.

Referring to FIG. 6, the adhesive layer 410 may include a first adhesive layer 411, a second adhesive layer 412, a third adhesive layer 413, and a fourth adhesive layer 414.

The refractive index of the second adhesive layer 412 may be greater than the refractive index of the first adhesive layer 411 and smaller than the refractive index of the first refractive layer 421.

The refractive index of the fourth adhesive layer 414 may be greater than the refractive index of the third adhesive layer 413 and smaller than the refractive index of the first refractive layer 421. The first adhesive layer 411 and the third adhesive layer 413 may be low refractive index layers. The second adhesive layer 412 and the fourth adhesive layer 414 may be middle refractive index layers. The refractive index of each of the adhesive layers 412 and 414 may range from 1.6 to 1.9, but the present disclosure is not limited thereto.

The adhesive layers 412 and 414 may include at least one or more from aluminum oxide (Al₂O₃), silicon oxynitride (SiON), yttrium oxide (Y₂O₃), magnesium oxide (MgO), and hafnium oxide (HfO₂), but the present disclosure is not limited thereto. The adhesive layers 412 and 414 are not limited to any material that achieves a middle refractive index in addition to the materials listed above. As characteristics of the anti-reflective film 400, in addition to low reflectivity, wear resistance against surface scratches and characteristics that minimize color deviation on curved surfaces may be required.

In order to improve wear resistance and reduce color deviation of curved surfaces while maintaining low reflectivity of the anti-reflective film 400, one may find materials with a greater difference in refractive index or one may increase the thickness of the refractive layer. But these methods may result in increased development time, increased production cost, and deterioration of the characteristics of the anti-reflective film 400. In the present disclosure, an adhesive layer 410 is bonded to the substrate SUB and the refractive layer so that color deviation due to the curvature of the film may be reduced. Further, the reflectivity of the film may be reduced by using a stack of layers including a low refractive index layer 411, a middle refractive index layer 412, a low refractive index layer 413, and a middle refractive index layer 414.

As the first adhesive layer 411 having a low refractive index directly contacts the substrate SUB, the adhesion force between the substrate SUB and the adhesive layer 410 may be improved.

In addition, as the low refractive index layers and the middle refractive index layers are alternately stacked, color deviation due to the curvature of the film may be reduced. When a high refractive index layer having a refractive index equal to or greater than 1.9 is added between the first adhesive layer 411, the second adhesive layer 412, the third adhesive layer 413, and the fourth adhesive layer 414 of the adhesive layer 410, it may be difficult to sufficiently reduce color deviation according to the curvature of the anti-reflective film 400. By using the adhesive layer 410 in which the first adhesive layer 411, the second adhesive layer 412, the third adhesive layer 413, and the fourth adhesive layer 414 are sequentially stacked, the reflectivity of the anti-reflective film 400 may be maintained while reducing color deviation due to curvature. The reflectivity of the anti-reflective film 400 may be equal to or less than 1.0%.

The anti-reflective film 400 may have a color deviation c* expressed by the following Equation 2 equal to or less than 6.0 at a curvature of 0° to 50°.

c*=\sqrt{da^{*2}+db^{*2}} [Equation 2]

In Equation 2, da* is the amount of change in the a* color coordinate at the changed curvature based on the a* color coordinate at 0°, and db* is the amount of change in the b* color coordinate at the changed curvature based on the b* color coordinate at 0°.

For example, at a curvature of 10°, the color deviation c* may be the square root of the sum of the squares of the differences between a* at 0° and a* at 10° and the squares of the differences between b* at 0° and b* at 10°.

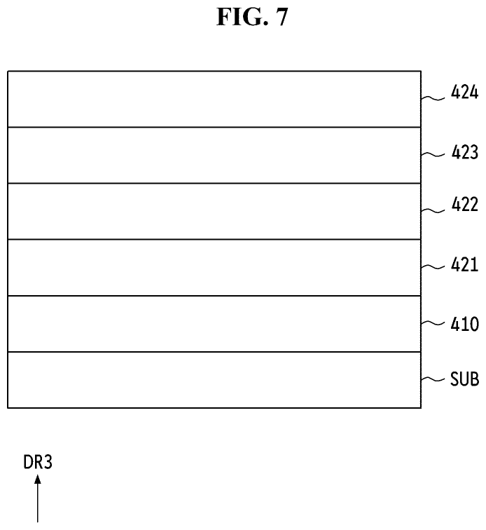

FIG. 7 illustrates an anti-reflective film in a display device according to a second aspect of the present disclosure.

The anti-reflective film illustrated in FIG. 7 is the same as the anti-reflective film illustrated in FIG. 5 except that it further includes a third refractive layer 423 and a fourth refractive layer 424, and therefore, overlapping description will be omitted hereafter.

The refractive index of the third refractive layer 423 may be greater than the refractive index of the fourth refractive layer 424.

The third refractive layer 423 may be a high refractive index layer.

The fourth refractive layer 424 may be a low refractive index layer. The third refractive layer 423 may have the characteristics of a high refractive index layer. The fourth refractive layer 424 may have the characteristics of a low refractive index layer.

The anti-reflective film 400 may be arranged in multiple layers by alternating high refractive index layers and low refractive index layers having distributed Bragg reflector (DBR) characteristics. Although the anti-reflective film 400 may have the first refractive layer 421, the second refractive layer 422, the third refractive layer 423 and the fourth refractive layer 424 stacked on one another as depicted in FIG. 7, the refractive layers 422 and 424 with a low refractive index and the refractive layers 421 and 423 with a high refractive index may be arranged alternately in multiple layers.

The layers in which the refractive layers 422 and 424 and the refractive layers 421 and 423 are alternately arranged may be referred to as a functional layer 420 of the anti-reflective film 400. The functional layer 420 may have structural characteristics that provide the reflectivity characteristics of the anti-reflective film 400. The characteristics of the anti-reflective film 400 may vary depending on the structure of the functional layer 420. The anti-reflective film 400 of the present disclosure may reduce color deviation due to curvature while maintaining reflectivity by simply adding the adhesive layer 410 without changing the structure of the functional layer 420. Since the structure of the functional layer 420 is not changed, characteristics according to that structure, such as rigidity, reflectivity, and durability of the anti-reflective film 400 may be maintained.

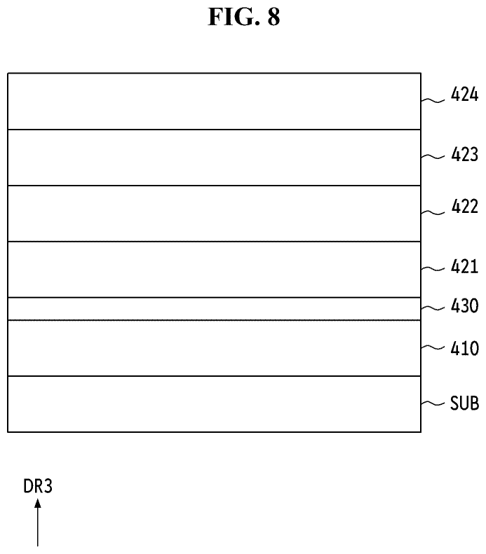

FIG. 8 illustrates an anti-reflective film in a display device according to a third aspect of the present disclosure. The anti-reflective film illustrated in FIG. 8 is the same as the anti-reflective film illustrated in FIG. 7 except that it further includes a dummy layer 430, and therefore, overlapping description will be omitted hereafter.

In FIG. 8, the dummy layer 430 may be located between the adhesive layer 410 and the first refractive layer 421, but the present disclosure is not limited thereto.

The dummy layer 430 may be located between the first refractive layer 421 and the second refractive layer 422, between the second refractive layer 422 and the third refractive layer 423, or between the third refractive layer 423 and the fourth refractive layer 424.

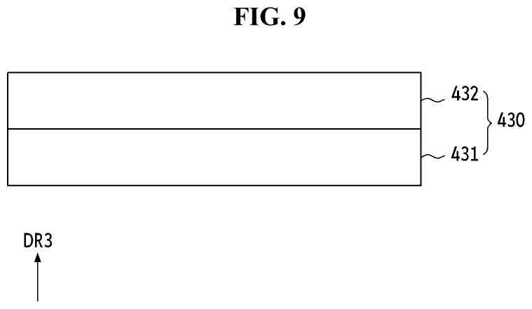

FIG. 9 is a cross-sectional view illustrating a dummy layer in an anti-reflective film in a display device according to an aspect of the present disclosure. The dummy layer 430 may include a first dummy layer 431 and a second dummy layer 432.

The refractive index of the first dummy layer 431 may be greater than the refractive index of the second dummy layer 432.

The first dummy layer 431 may be a high refractive index layer. The second dummy layer 432 may be a low refractive index layer. The thickness of the first dummy layer 431 and the thickness of the second dummy layer 432 may each independently be 80 nm or less. When the thin dummy layer 430 is added, the durability of the anti-reflective film 400 may be improved while maintaining the reflectivity of the functional layer 420.

When the thickness of the first dummy layer 431 or the thickness of the second dummy layer 432 is greater than 80 nm, the reflectivity of the anti-reflective film 400 may be affected. Hereinafter, the aspects of the present disclosure will be described in more detail. It should be understood that the aspects of the present disclosure are merely illustrative and are not intended to limit the scope of the present disclosure.

### 1. Preparation of Anti-Reflective film

Anti-reflective films of Example 1, Example 2, Comparative Example 1, and Comparative Example 2 were fabricated with reference to Tables 1 and 2 below.

The high refractive index layers (the first refractive layer, third refractive layer, fifth refractive layer, seventh refractive layer, and ninth refractive layer) of Example 1 and Comparative Example 1 were stacked using silicon nitride (Si₃N₄) to the thicknesses shown in Table 1 below.

The low refractive-index layers (the second refractive layer, fourth refractive layer, sixth refractive layer, eighth refractive layer, and tenth refractive layer) of Example 1 and Comparative Example 1 were stacked using silicon oxide (SiO₂) to the thicknesses shown in Table 1 below.

In Example 1, the adhesive layer comprises a first to fourth adhesive layers bonded together. Silicon oxide (SiO₂) was used in the first and third adhesive layers, and silicon oxynitride (SiON) was used in the second and fourth adhesive layers.

In Comparative example 1, silicon oxide (SiO₂) was used in the adhesive layer.

TABLE 1

| | Comparative | Example |
|---|---|---|
| Thicknesses(nm) | Example 1 | 1 |
| Tenth refractive layer | 91.8 | 90.3 |
| Ninth refractive layer | 104.9 | 127 |
| Eighth refractive layer | 8.0 | 23.2 |
| Seventh refractive layer | 38.6 | 20.3 |
| Sixth refractive layer | 59.7 | 70.6 |
| Fifth refractive layer | 27.3 | 19.8 |
| Fourth refractive layer | 48.8 | 47.4 |
| Third refractive layer | 157.4 | 152.7 |
| Second refractive layer | 39.0 | 37.1 |
| First refractive layer | 20.1 | 12.4 |
| Fourth adhesive layer | 55.2 | 16.7 |
| Third adhesive layer | — | 102.7 |
| Second adhesive layer | — | 8.0 |
| First adhesive layer | — | 62.4 |
| Total thickness | 650.8 | 790.7 |

The middle refractive index layers (the first refractive layer, third refractive layer, fifth refractive layer, seventh refractive layer, ninth refractive layer, and eleventh refractive layer) of Example 2 and Comparative Example 2 were stacked using silicon oxynitride (SiON) to a thickness as shown in Table 2 below.

The low refractive index layers (the second refractive layer, fourth refractive layer, sixth refractive layer, eighth refractive layer, tenth refractive layer, and twelfth refractive layer) of Example 2 and Comparative Example 2 were stacked using silicon oxide (SiO₂) to the thicknesses as shown in Table 2 below.

In Example 2, the adhesive layer comprising a first to fourth adhesive layers are bonded together. Silicon oxide (SiO₂) was used in the first and third adhesive layers, and silicon oxynitride (SiON) was used in the second and fourth adhesive layers.

In Comparative example 2, silicon oxynitride (SiON) was used in the adhesive layer.

TABLE 2

| | Comparative | Example |
|---|---|---|
| Thicknesses(nm) | Example 2 | 2 |
| Twelfth refractive layer | 97.2 | 95.8 |
| Eleventh refractive layer | 65.4 | 63.4 |
| Tenth refractive layer | 8.1 | 8.0 |
| Ninth refractive layer | 67.0 | 67.0 |
| Eighth refractive layer | 66.4 | 68.2 |
| Seventh refractive layer | 21.8 | 19.1 |
| Sixth refractive layer | 51.1 | 53.7 |
| Fifth refractive layer | 175.7 | 170.5 |
| Fourth refractive layer | 20.1 | 23.0 |
| Third refractive layer | 60.8 | 58.1 |
| Second refractive layer | 29.5 | 27.6 |
| First refractive layer | 38.5 | 44.5 |
| Fourth adhesive layer | 99.0 | 104.0 |
| Third adhesive layer | — | 76.8 |
| Second adhesive layer | — | 11.0 |
| First adhesive layer | — | 66.8 |
| Total thickness | 800.5 | 957.5 |

### [Evaluation]

### 1. Reflectivity and Color Deviation Characteristics

The optical properties and rigidity of Example 1, Example 2, Comparative Example 1, and Comparative Example 2 were measured, and the results are shown in Table 3 below.

TABLE 3

| | | Comparative | Exam- | Comparative | Exam- |
|---|---|---|---|---|---|
| Characteristics | | Example 1 | ple 1 | Example 2 | ple 2 |
| Optical | R | 0.51% | 0.49% | 0.56% | 0.52% |
| properties | a* | −0.4 | −0.4 | −0.4 | −0.4 |
| | b* | −0.64 | −0.95 | −1.39 | −0.81 |
| Rigidity (GPa) | | 15.4 | 15 | 17 | 16.8 |

In Table 3, R is the reflectivity, a* and b* are color coordinates, and the rigidity is measured at a surface of the anti-reflective film.

According to the results shown in Table 3, when comparing Example 1 and Comparative Example 1 having the same functional layer, it can be confirmed that the reflectivity of Example 1 was reduced.

Compared to Comparative Example 1, it can be confirmed that the rigidity of Example 1 is lowered, but maintains a higher value than the rigidity required as an anti-reflective film.

It can be confirmed that the color differences of Example 1 and Comparative Example 1 are similar. When comparing Example 2 and Comparative Example 2, which have the same functional layer, it can be confirmed that the reflectivity of Example 2 is reduced. Compared to

Comparative Example 2, it can be confirmed that the rigidity of Example 2 is lowered, but maintains a higher value than the rigidity required as an anti-reflective film. It can be confirmed that the color differences of Example 2 and Comparative Example 2 are similar.

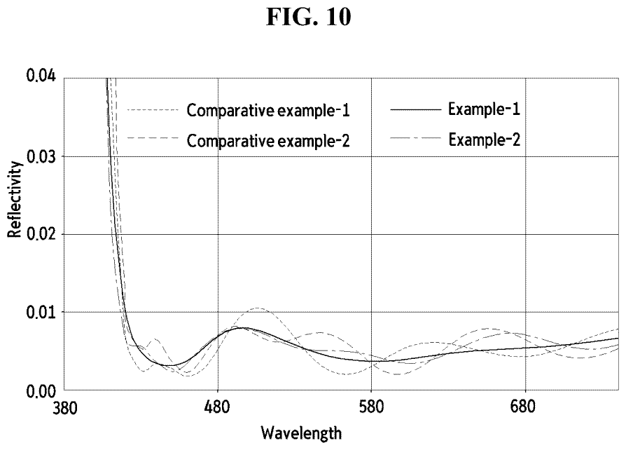

FIG. 10 is a graph showing reflectivity according to wavelength of anti-reflective films of Example 1, Example 2, Comparative example 1, and Comparative example 2.

According to the results shown in FIG. 10, when comparing Example 1 and Comparative Example 1 having the same functional layer, it can be confirmed that the reflectivity peak of Comparative Example 1, which appears around 500 nm and 600 nm, has disappeared in Example 1. Similarly, when comparing Example 2 and Comparative Example 2having the same functional layer, it can be confirmed that the reflectivity peak of Comparative Example 2, which appears around 550 nm and 650 nm, disappears in Example 2. If the reflectivity is high at a specific wavelength, color deviation may occur. When using a low refractive index layer/middle refractive index layer/low refractive index layer/middle refractive index layer in sequence as an adhesive layer of an anti-reflective film, it can be confirmed that the reflectivity, color difference, and rigidity may be maintained while reducing color deviation.

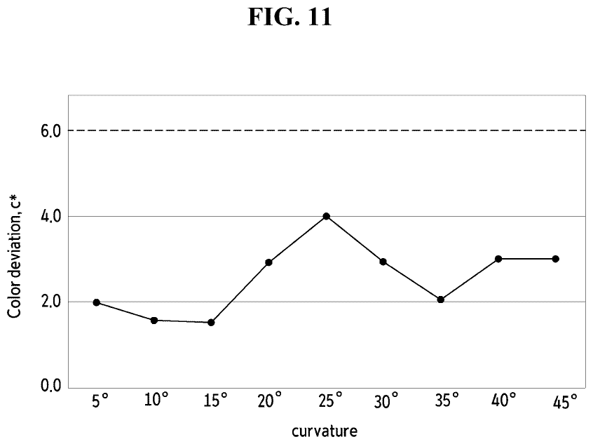

FIG. 11 is a graph showing color deviation (c*) according to the curvature of the anti-reflective film of Example 1.

According to the results shown in FIG. 11, it can be confirmed that the color deviation of Example 1 is 6.0 or less at a curvature of 0° to 45°. An anti-reflective film that maintains low color deviation even when curvature increases may be applied to non-planar displays. Non-planar displays that apply the anti-reflective film of the present disclosure may have low reflectivity and low color deviation according to curvature.

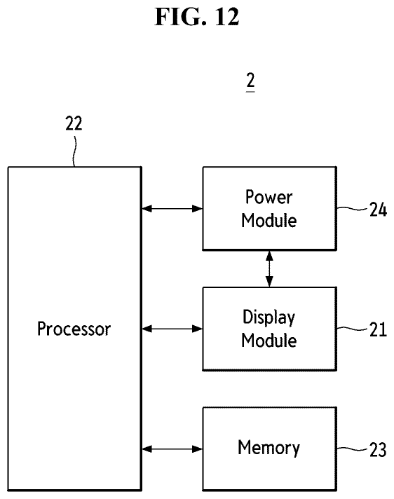

FIG. 12 is a block diagram of an electronic device according to an aspect.

Referring to FIG. 12, an electronic device 2 according to an aspect of the present disclosure may include a display module 21, a processor 22, a memory 23, and a power module 24.

The processor 22 may include at least one of: a central processing unit (CPU), an application processor (AP), a graphic processing unit (GPU), a communication processor (CP), an image signal processor (ISP), and a controller.

The memory 23 may store data information required for the operation of the processor 22 or the display module 21. When the processor 22 executes an application stored in the memory 23, an image data signal and/or an input control signal may be transmitted to the display module 21. The display module 21 may process the received signal and output image information through a display screen.

The power module 24 may include a power supply module such as a power adapter and a battery device, and a power conversion module that converts the power supplied by the power supply module to generate power required for the operation of the electronic device 2.

At least one of the elements of the electronic device 2 described above may be included in the display device 1 according to the aspects described above. In addition, some of the individual modules functioning as a single module may be included in the display device 1 while some others may be provided separately from the display device 1. For example, the display device 1 may include the display module 21, and the processor 22, the memory 23 and the power module 24 may be provided as other devices inside the electronic device 2 than the display device 1.

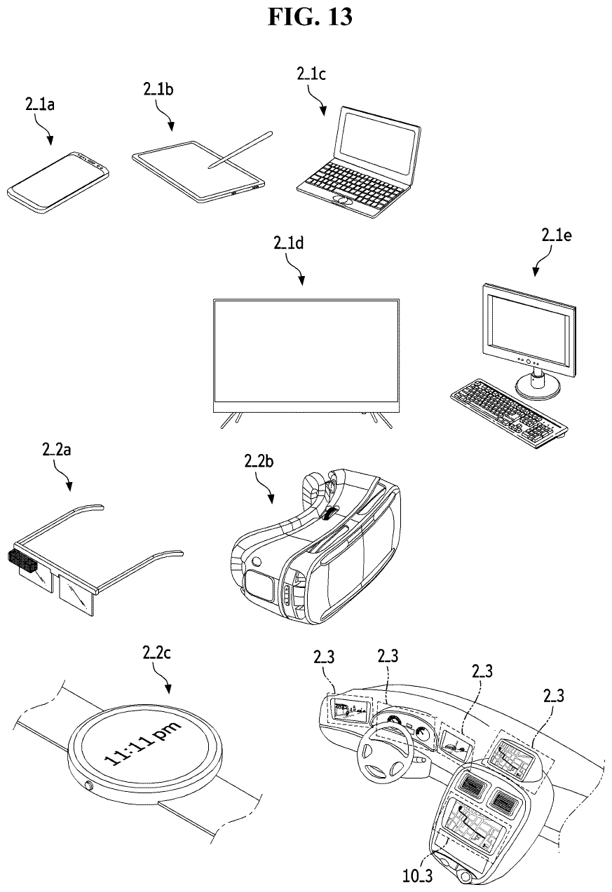

FIG. 13 is a view showing electronic devices according to a variety of aspects of the present disclosure.

Referring to FIG. 13, a variety of electronic devices 2 employing the display devices according to the aspects may include not only electronic devices for display images such as a smart phone 2_la, a tablet PC 2_1b, a laptop computer 2_1c, a TV 2_1d and a desktop monitor 2 le, but also wearable electronic devices including display modules such as smart glasses 2_2a, a head-mounted display 2_2b and a smart watch 2_2c, and electronic devices for vehicles 2_3 including display modules such as a center information display (CID) placed on the dashboard, the center fascia and the dashboard of a vehicle, and a room mirror display.

Although the aspects of the present disclosure have been described with reference to the attached drawings, those skilled in the art will understand that the present disclosure can be implemented in other specific forms without changing the technical idea or essential features of the present disclosure. Therefore, it should be understood that the aspects described above are exemplary in all respects and not restrictive.

What is claimed is:

1. An anti-reflective film comprising:
a substrate;
an adhesive layer located on the substrate;
a first refractive layer located on the adhesive layer;
and a second refractive layer located on the first refractive layer, wherein a refractive index of the first refractive layer is greater than a refractive index of the second refractive layer,
wherein the adhesive layer comprises:
a first adhesive layer;
a second adhesive layer located on the first adhesive layer;
a third adhesive layer located on the second adhesive layer; and
a fourth adhesive layer located on the third adhesive layer,
wherein a refractive index of the second adhesive layer is greater than a refractive index of the first adhesive layer and smaller than the refractive index of the first refractive layer, and
a refractive index of the fourth adhesive layer is greater than a refractive index third adhesive layer and smaller than the refractive index of the first refractive layer.

2. The anti-reflective film of claim 1,
wherein the refractive index of the first refractive layer is equal to or more than 1.9, and the refractive index of the second refractive layer is equal to or less than 1.6.

3. The anti-reflective film of claim 2,
wherein the refractive index of the second adhesive layer and the refractive index of the fourth adhesive layer range from 1.6 to 1.9.

4. The anti-reflective film of claim 1,
wherein a reflectivity of the anti-reflective film is equal to or less than 1.0%.

5. The anti-reflective film of claim 1,
wherein a color deviation c* of the anti-reflective film is equal to or less than 6.0 at a curvature of 0° to 50°, where
c*=\sqrt{da^{*2}+db^{*2}},
da* is the change in an a* color coordinate at the curvature relative to an a* color coordinate at 0°, and db* is the change in a b* color coordinate at the curvature relative to a b* color coordinate at 0°.

6. The anti-reflective film of claim 1, further comprising:
a third refractive layer located on the second refractive layer; and
a fourth refractive layer located on the third refractive layer,
wherein a refractive index of the third refractive layer is greater than a refractive index of the fourth refractive layer.

7. The anti-reflective film of claim 6, further comprising:
a dummy layer between the adhesive layer and the first refractive layer, between the first and the second refractive layers, between the second and the third refractive layers, or between the third and the fourth refractive layers,
wherein the dummy layer comprises a first dummy layer and a second dummy layer located on the first dummy layer,
a refractive index of the first dummy layer is greater than a refractive index of the second dummy layer, and
a thickness of the first dummy layer and a thickness of the second dummy layer are equal to or less than 80 nm.

8. A display device comprising:
a display panel; and
an anti-reflective film located on the display panel,
wherein the anti-reflective film comprises:
an adhesive layer located on the display panel;
a first refractive index layer located on the adhesive layer; and
a second refractive index layer located on the first refractive index layer,
wherein a refractive index of the first refractive layer is greater than a refractive index of the second refractive layer,
wherein the adhesive layer comprises:
a first adhesive layer;
a second adhesive layer located on the first adhesive layer;
a third adhesive layer located on the second adhesive layer; and
a fourth adhesive layer located on the third adhesive layer,
wherein a refractive index of the second adhesive layer is greater than a refractive index of the first adhesive layer and smaller than the refractive index of the first refractive layer, and
a refractive index of the fourth adhesive layer is greater than a refractive index third adhesive layer and smaller than the refractive index of the first refractive layer.

9. The display device of claim 8,
wherein the refractive index of the first refractive layer is equal to or more than 1.9,and the refractive index of the second refractive layer is equal to or less than 1.6.

10. The display device of claim 9,
wherein the wherein the refractive index of the second adhesive layer and the refractive index of the fourth adhesive layer range from 1.6 to 1.9.

11. The display device of claim 8,
wherein a reflectivity of the anti-reflective film is equal to or less than 1.0%.

12. The display device of claim 8,
wherein a color deviation c* of the anti-reflective film is equal to or less than 6.0 at a curvature of 0° to 50°, where
c*=\sqrt{da^{*2}+db^{*2}},
da* is the change in an a* color coordinate at the curvature relative to an a* color coordinate at 0°, and db* is the change in a b* color coordinate at the curvature relative to a b* color coordinate at 0°.

13. The display device of claim 8,
wherein the anti-reflective film further comprises:
a third refractive layer located on the second refractive layer; and
a fourth refractive layer located on the third refractive layer,
wherein a refractive index of the third refractive layer is greater than a refractive index of the fourth refractive layer.

14. The display device of claim 13, further comprising:
a dummy layer between the adhesive layer and the first refractive layer, between the first and the second refractive layers, between the second and the third refractive layers, or between the third and the fourth refractive layers,
wherein the dummy layer comprises a first dummy layer and a second dummy layer located on the first dummy layer,
a refractive index of the first dummy layer is greater than a refractive index of the second dummy layer, and
a thickness of the first dummy layer and a thickness of the second dummy layer are equal to or less than 80 nm.

15. An electronic device comprising:
a display device providing an image; and
a processor transmitting an image data signal to the display device,
wherein the display device comprises:
a display panel;
and an anti-reflective film located on the display panel,
wherein the anti-reflective film comprises:
an adhesive layer located on the display panel;
a first refractive index layer located on the adhesive layer; and
a second refractive index layer located on the first refractive index layer,
wherein a refractive index of the first refractive layer is greater than a refractive index of the second refractive layer,
wherein the adhesive layer comprises:
a first adhesive layer;
a second adhesive layer located on the first adhesive layer;
a third adhesive layer located on the second adhesive layer; and
a fourth adhesive layer located on the third adhesive layer,
wherein a refractive index of the second adhesive layer is greater than a refractive index of the first adhesive layer and smaller than the refractive index of the first refractive layer, and
a refractive index of the fourth adhesive layer is greater than a refractive index third adhesive layer and smaller than the refractive index of the first refractive layer.

16. The electronic device of claim 15,
wherein the refractive index of the first refractive layer is equal to or greater than 1.9,the refractive index of the second refractive layer is equal to or less than 1.6, and the refractive index of the second adhesive layer and the refractive index of the fourth adhesive layer range from 1.6 to 1.9.

17. The electronic device of claim 15,
wherein a reflectivity of the anti-reflective film is equal to or less than 1.0%.

18. The electronic device of claim 15,
wherein a color deviation c* of the anti-reflective film is equal to or less than 6.0 at a curvature of 0° to 50°, where
c*=\sqrt{da^{*2}+db^{*2}},
da* is the change in an a* color coordinate at the curvature relative to an a* color coordinate at 0°, and db* is the change in a b* color coordinate at the curvature relative to a b* color coordinate at 0°.

19. The electronic device of claim 15,
wherein the anti-reflective film further comprises:
a third refractive layer located on the second refractive layer; and
a fourth refractive layer located on the third refractive layer,
wherein a refractive index of the third refractive layer is greater than a refractive index of the fourth refractive layer.

20. The electronic device of claim 19, further comprising:
a dummy layer between the adhesive layer and the first refractive layer, between the first and the second refractive layers, between the second and the third refractive layers, or between the third and the fourth refractive layers,
wherein the dummy layer comprises a first dummy layer and a second dummy layer located on the first dummy layer,
a refractive index of the first dummy layer is greater than a refractive index of the second dummy layer, and
a thickness of the first dummy layer and a thickness of the second dummy layer are equal to or less than 80 nm.
